(19) United States
(12) Patent Application Publication
(10) Pub. No.: US 2025/0192522 A1
(43) Pub. Date: Jun. 12, 2025

(54) SURFACE-EMITTING LASER DEVICE, DETECTION APPARATUS, AND MOBILE OBJECT

(71) Applicant: Ryoichiro SUZUKI, Miyagi (JP)

(72) Inventor: Ryoichiro SUZUKI, Miyagi (JP)

(21) Appl. No.: 18/844,410

(22) PCT Filed: Feb. 16, 2023
(86) PCT No.: PCT/IB2023/051391

§ 371 Date: Sep. 6, 2024

(30) Foreign Application Priority Data
Mar. 10, 2022 (JP) 2022-037461
Dec. 21, 2022 (JP) 2022-204673

(51) Int. Cl. H01S 5/34

(52) U.S. Cl. CPC H01S 5/3403; H01S 5/3416

(57) ABSTRACT

A surface-emitting laser device includes: a first reflector; a second reflector; and a resonator region between the first reflector and the second reflector. The resonator region includes: multiple active layers each having first crystal strain in one of a compression direction and a tension direction; a tunnel junction layer between the multiple active layers; and a strain relaxation layer having second crystal strain in another of the compression direction and the tension direction opposite to the first crystal strain of the multiple active layers.

### TECHNICAL FIELD

The present disclosure relates to a surface-emitting laser device, a detection apparatus, and a mobile object.

### BACKGROUND ART

A vertical cavity surface emitting laser (VCSEL) is a semiconductor laser that oscillates a laser beam in a direction perpendicular to a substrate. The VCSEL allows lower cost, lower power consumption, smaller size, and higher performance and facilitates two-dimensional integration than the edge-emitting semiconductor lasers.

The VCSEL has a resonator structure including a resonator area including an active layer, an upper Bragg reflector on the upper side of the resonator area, and a lower Bragg reflector on the lower side of the resonator area. The resonator area has a predetermined optical thickness to allow resonation of light having a wavelength λ in the resonator area, so as to obtain light having the oscillation wavelength 2. The upper Bragg reflector and the lower Bragg reflector are each composed of a distributed Bragg reflector (DBR) in which materials of different refractive indexes, i.e., low refractive index materials and high refractive index materials are alternately stacked on top of each other. In the DBR, in order to obtain a high reflectance at a wavelength λ, the low refractive index material and the high refractive index material are formed to have an optical film thickness of λ/4 in consideration of the refractive index of each material.

A widely known multi-junction surface-emitting laser includes multiple sets of resonator areas, each including an active layer, in a lamination direction. Such a multi-junction surface-emitting laser enables high-power laser output. The multi-junction surface-emitting laser is referred to also as a cascade surface-emitting laser. The multi-junction surface-emitting laser including more active layers outputs higher output power laser. Further, the tunnel junction layer between the active layers in the multi-junction surface-emitting laser allows carriers to be uniformly injected into all the active layers and thus effectively increases laser output power.

### Citation List

### Patent Literature

### [PTL 1]

Japanese Patent No. 4232334

### [NTL 1]

“Multi-junction vertical-cavity surface-emitting lasers in the 800-1100 nm wavelength range”, Proc. SPIE 11704, Vertical-Cavity Surface-Emitting Lasers XXV, 117040B (5 Mar. 2021).

### [NTL 2]

Semiconductor Laser Applied Physics Society ed., Ohmsha, Ltd.

### SUMMARY OF INVENTION

### Technical Problem

A semiconductor laser including a surface-emitting laser with each active layer given with crystal strain in a compression direction enables an increase in optical gain during laser operation and a reduction in oscillation threshold current and achieves a higher optical power output. However, more active layers included in the multi-junction surface-emitting laser to increase output power accumulate more crystal distortion and adversely increase crystal strain in the resonator area. With the total thickness of the active layers exceeding the critical film thickness, crystal defects such as misfit dislocations occur. For this reason, a conventional surface-emitting laser having such a multi-junction structure has difficulties in higher output power.

Non Patent Literature (NPL) 1 has a suggestion of the limitation on the number of active layers due to crystal strain. Patent Literature (PTL) 1 has a description that GaInNAs, GaNAs, GAPsb, or the like is used for the tunnel junction layer. However, these technologies have difficulties with the high power output of the surface-emitting laser device. An object of the present disclosure aims to provide a surface-emitting laser device that achieves a high power output, a detection apparatus incorporating the surface-emitting laser device, and a mobile object incorporating the detection apparatus.

### Solution to Problem

A surface-emitting laser device includes: a first reflector; a second reflector; and a resonator region between the first reflector and the second reflector. The resonator region includes multiple active layers each having first crystal strain in one of a compression direction and a tension direction; a tunnel junction layer between the multiple active layers; and a strain relaxation layer having second crystal strain in another of the compression direction and the tension direction opposite to the first crystal strain of the multiple active layers.

### Advantageous Effects of Invention

The technologies according to embodiments of the present disclosure achieve a high output.

### BRIEF DESCRIPTION OF DRAWINGS

The accompanying drawings are intended to depict example embodiments of the present invention and should not be interpreted to limit the scope thereof. The accompanying drawings are not to be considered as drawn to scale unless explicitly noted. Also, identical or similar reference numerals designate identical or similar components throughout the several views.

FIG. 1 is a cross-sectional view of a surface-emitting laser device according to a first embodiment of the present disclosure.

FIG. 2 is a cross-sectional view of a part of the surface-emitting laser device in FIG. 2.

FIG. 3 is a cross-sectional view of a surface-emitting laser device according to a third embodiment of the present disclosure.

FIG. 4 is a cross-sectional view of a part of the surface-emitting laser device in FIG. 3.

FIG. 5 is a diagram of a distance measurement apparatus according to a fourth embodiment of the present disclosure.

FIG. 6 is a diagram of a mobile object according to a fifth embodiment of the present disclosure.

FIG. 7 is a diagram of the configuration of an optical examination apparatus according to a sixth embodiment of the present disclosure.

FIG. 8 is a block diagram of the configuration of an optical inspection apparatus in FIG. 7.

### DESCRIPTION OF EMBODIMENTS

The terminology used herein is for the purpose of describing particular embodiments only and is not intended to be limiting of the present invention. As used herein, the singular forms “a,” “an,” and “the” are intended to include the plural forms as well, unless the context clearly indicates otherwise.

In describing embodiments illustrated in the drawings, specific terminology is employed for the sake of clarity. However, the disclosure of this specification is not intended to be limited to the specific terminology so selected and it is to be understood that each specific element includes all technical equivalents that have a similar function, operate in a similar manner, and achieve a similar result.

Embodiments of the present disclosure are described below with reference to the accompanying drawings. In the specification and the drawings, components having substantially the same functional configuration are denoted by the same reference sign, and redundant description may be omitted.

### First Embodiment

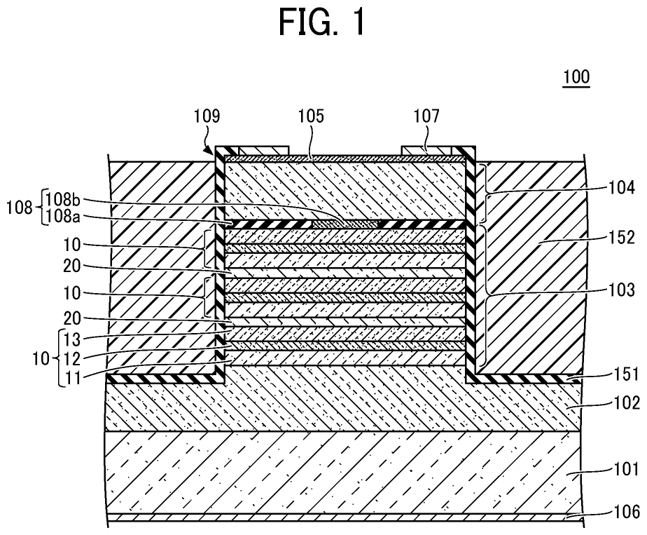

First, a first embodiment will be described. The first embodiment relates to a surface-emitting laser device. FIG. 1 is a cross-sectional view of a surface-emitting laser device according to the first embodiment of the present disclosure.

The surface-emitting laser device 100 according to the first embodiment is a surface-emitting laser device having an oscillation wavelength 2 of 940 nm. The surface-emitting laser device 100 includes a substrate 101, a lower distributed Bragg reflector (DBR) 102 (a first reflector), a resonator region 103, an upper DBR 104 (a second reflector), a contact layer 105, a lower electrode 106, and an upper electrode 107. The lower DBR 102 overlies the substrate 101, and the resonator region 103 overlies the lower DBR 102. The upper DBR 104 overlies the resonator region 103, and the contact layer 105 overlies the upper DBR 104. The lower DBR 102, the resonator region 103, the upper DBR 104, and the contact layer 105 are formed by laminating semiconducting layers on the upper surface (a first surface) of the substrate 101. The lower electrode 106 is disposed on the back surface (a second surface) of the substrate 101, and the upper electrode 107 is disposed on the surface of the contact layer 105. The surface-emitting laser device 100 emits a laser beam upward from the resonator region 103. The surface-emitting laser device 100 is a top-emitting vertical cavity surface-emitting laser (VCSEL) device.

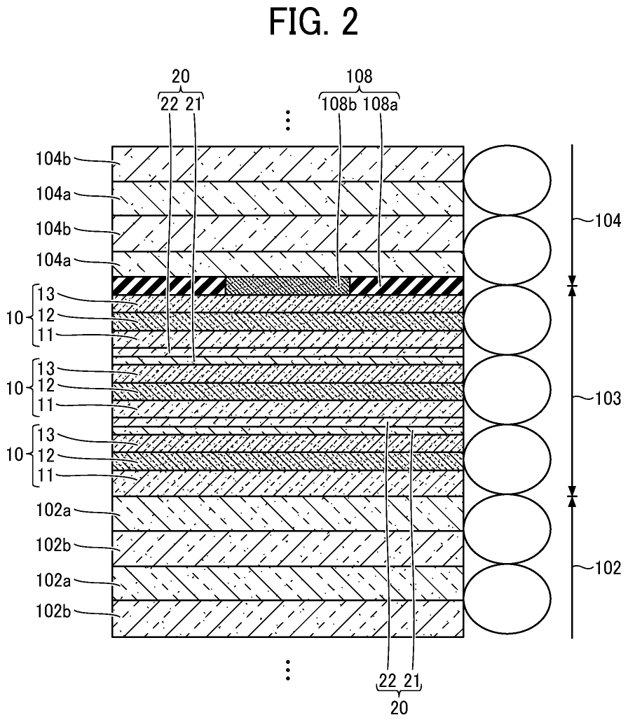

The substrate 101 is composed of an n-GaAs substrate which is a semiconductor substrate. The lower DBR 102 is formed by alternately stacking 35.5 pairs of high refractive index layers 102a of n-Al_{0.1}Ga_{0.9}As and low refractive index layers 102b of n-Al_{0.9}Ga_{0.1}As, each layer having an optical thickness of λ/4 (see FIG. 2). In other words, the lower DBR 102 includes 36 high refractive index layers 102a of n-Al_{0.1}Ga_{0.9}As and 35 low refractive index layers 102b of n-Al_{0.9}Ga_{0.1}As.

The resonator region 103 includes three laminate bodies 10 stacked on each other. The resonator region 103 further includes a tunnel junction layer 20 between the laminate bodies 10 adjacent to each other in the thickness direction of the surface-emitting laser device 100. Each laminate body 10 includes a lower spacer layer 11, an active layer 12, and an upper spacer layer 13. In each laminate body 10, the active layer 12 overlies the lower spacer layer 11, and the upper spacer layer 13 overlies the active layer 12. The tunnel junction layer 20 includes a p-type layer 21 and an n-type layer 22 (see FIG. 2). The n-type layer 22 overlies the p-type layer 21.

The lower spacer layer 11 and the upper spacer layer 13 are, for example, Al_{0.65}Ga_{0.35}As_{0.925}P_{0.075} layers. The active layer 12 has a quantum well structure in which GaInAs quantum well layers and AlGaAs barrier layers are alternately stacked. For example, the GaInAs quantum well layer has a thickness of 8 nm. For example, three GaInAs quantum well layers are included in one active layer 12. The lattice constant of the active layer 12 having such a composition is greater than the lattice constant of GaAs constituting the substrate 101. The lattice constant of Al_{0.65}Ga_{0.35}As_{0.925}P_{0.075} constituting the lower spacer layer 11 and the upper spacer layer 13 is smaller than the lattice constant of GaAs. The total thickness of the lower spacer layer 11 and the upper spacer layer 13, which may vary with the position of the laminate body 10, are approximately 80 nm. Although details will be described later, in the present embodiment, the GaInAs quantum well layer contains crystal strain of 0.9% with respect to the GaAs substrate in a compressive direction. In the first embodiment, each of the lower spacer layer 11 and the upper spacer layer 13 is an example of a strain relaxation layer.

The p-type layer 21 is a p⁺⁺-GaAs layer having a p-type impurity concentration of 10¹⁹ cm⁻³ or more, and the n-type layer 22 is an n⁺⁺-GaAs layer having an n-type impurity concentration of 10¹⁹ cm⁻³ or more. The p-type layer 21 and the n-type layer 22 are stacked on each other to form a tunnel junction. Electrons in the conduction band of the n-type layer 22 move toward the valence band of the p-type layer 21, so that a tunnel current flows between the bands. The tunnel junction layer 20 converts the polarity of the charge carrying the current from n-type to p-type.

The upper DBR 104 is formed by alternately stacking 20 pairs of high refractive index layers 104a of p-Al_{0.1}Ga_{0.9}As and low refractive index layers 104b of p-Al_{0.9}Ga_{0.1}As, each layer having an optical thickness of A/4 (see FIG. 2). In other words, the upper DBR 104 includes 20 high refractive index layers 104a of p-Al_{0.1}Ga_{0.9}As and 20 low refractive index layers 104b of p-Al_{0.9}Ga_{0.1}As.

The surface-emitting laser device 100 includes a current confinement layer 108 between the uppermost laminate body 10 among the three laminate bodies 10 and the lowermost high refractive index layer 104a of p-Al_{0.1}Ga_{0.9}As among 20 high refractive index layers 104a of p-Al_{0.1}Ga_{0.9}As. The current confinement layer 108 includes a selectively-oxidized region 108a and a current confinement region 108b. The current confinement region 108b is surrounded by the selectively-oxidized region 108a. The current confinement layer 108 is formed by selective oxidation of p-AlAs, for example. A lower portion of the current confinement layer 108 is included in the resonator region 103, and an upper portion of the current confinement layer 108 is included in the upper DBR 104.

The contact layer 105 is formed of p+-GaAs. A mesa 109 is formed in part of the contact layer 105, the upper DBR 104, the resonator region 103, and the lower DBR 102. The surface-emitting laser device 100 includes a protective layer 151 that covers the side surface of the mesa 109 and the upper surface of the lower DBR 102. The protective layer 151 is composed of, for example, a dielectric such as SiN. Further, a resin layer 152 is formed by embedding a resin material such as polyimide in a region created by removing the semiconductor layer to form the mesa 109.

The resonator region 103 is described below in more detail. FIG. 2 is a cross-sectional view of a part of the surface-emitting laser device 100 according to the first embodiment. The waveform illustrated on the right side of the cross-sectional structure in FIG. 2 schematically indicates the waveform of the normalized longitudinal mode.

In the surface-emitting laser device 100, the optical thickness of each of the laminate bodies 10 is λ/2 or less, and an antinode of the normalized longitudinal mode is located at each of the active layers 12.

The lowermost laminate body 10 among the laminate bodies 10 and the p-type layer 21 immediately above the lowermost laminate body 10 have an optical thickness λ/2 in total. A node of the normalized longitudinal mode is located at the boundary between the lowermost laminate body 10 and the lower DBR 102, and another node is located at the boundary between the p-type layer 21 and the n-type layer 22 included in the tunnel junction layer 20 immediately above the lowermost laminate body 10. This indicates that the lowermost laminate body 10 and the p-type layer 21 immediately above the lowermost laminate body 10 serve as one λ/2 resonator.

The central laminate body 10 among the laminate bodies 10, the n-type layer 22 immediately below the central laminate body 10, and the p-type layer 21 immediately above the central laminate body 10 have an optical thickness λ/2 in total. A node of the normalized longitudinal mode is located at the boundary between the p-type layer 21 and the n-type layer 22 included in the tunnel junction layer 20 immediately below the central laminate body 10, and another node is located at the boundary between the p-type layer 21 and the n-type layer 22 included in the tunnel junction layer 20 immediately above the central laminate body 10. This indicates that the central laminate body 10, the n-type layer 22 immediately below the central laminate body 10, and the p-type layer 21 immediately above the central laminate body 10 serve as one λ/2 resonator.

The uppermost laminate body 10 among the laminate bodies 10, the n-type layer 22 immediately below the uppermost laminate body 10, and a portion of the current confinement layer 108 immediately above the uppermost laminate body 10 have an optical thickness λ/2 in total. A node of the normalized longitudinal mode is located at the boundary between the p-type layer 21 and the n-type layer 22 included in the tunnel junction layer 20 immediately below the uppermost laminate body 10, and another node is located at the portion of the current confinement layer 108 immediately above the uppermost laminate body 10. This indicates that the uppermost laminate body 10, the n-type layer 22 immediately below the uppermost laminate body 10, and the portion of the current confinement layer 108 immediately above the uppermost laminate body 10 serve as one λ/2 resonator.

The optical thickness of the resonator region 103 is 3λ/2.

A crystal strain ε// in a direction parallel to a surface of a substrate (i.e., in-plane direction) generated in a semiconductor layer epitaxially grown on the surface of the substrate is typically given by the following formula (1) where aₑₚᵢ is the lattice constant of the semiconductor layer, and a_{sub} is the lattice constant of the substrate.

ε//=−(aₑₚᵢ−a_{sub})/a_{sub} (1)

When the lattice constant aₑₚᵢ is greater than the lattice constant a_{sub}, the crystal strain ε// is negative. In this case, crystal strain (compressive strain) in the compression direction occurs in the semiconductor layer. When the lattice constant aₑₚᵢ is smaller than the lattice constant a_{sub}, the crystal strain ε// is positive. In this case, crystal strain (tensile strain) in a tension direction occurs in the semiconductor layer.

In the present embodiment as described above, the lattice constant of the active layer 12 is greater than the lattice constant of GaAs constituting the substrate 101, and the lattice constants of the lower spacer layer 11 and the upper spacer layer 13 are smaller than the lattice constant of GaAs. In this configuration, the active layer 12 contains a compressive strain, and the lower spacer layer 11 and the upper spacer layer 13 contain a tensile strain. In other words, the lower spacer layer 11 and the upper spacer layer 13 contain crystal strain in a direction opposite to that of the active layer 12 in the in-plane direction. In each laminate body 10, the crystal strain of the active layer 12 and the crystal strain of the lower spacer layer 11 and the upper spacer layer 13 are canceled out.

In the present embodiment, the GaInAs quantum well layer included in the active layer 12 has a crystal strain of 0.9% in the compressive direction and has a thickness of 8 nm. For the active layer 12 including three GaInAs quantum well layers stacked on each other, the total compressive strain in the active layer 12 is 21.6% nm (3×0.9%×8 nm=21.6% nm). The lower spacer layer 11 and the upper spacer layer 13 having a total tensile strain of 21.6% nm in one laminate body 10 cancel out the crystal strain in the laminate body 10. To cancel out crystal strain in each laminate body 10, the lower spacer layer 11 and the upper spacer layer 13 having a total thickness of 80 nm are formed to have a tensile strain of 0.27% in total. Alternatively, the lower spacer layer 11 and the upper spacer layer 13, both of which are AlGaAsP layers, are formed to have a composition ratio of P in the group V element being 7.5%, so as to cancel out the crystal strain. Since the lattice constant of the AlGaAs barrier layer is substantially equal to the lattice constant of the GaAs substrate, the crystal strain of the AlGaAs barrier layer is not considered.

The number of quantum well layers included in the active layer 12 is not limited to three. For example, the active layer 12 including one quantum well layer has a compressive strain of 7.2% nm (1×0.9%×8 nm=7.2% nm) in total. To cancel out crystal strain in each laminate body 10, the lower spacer layer 11 and the upper spacer layer 13 having a total thickness of 80 nm are formed to have a tensile strain of 0.09% in total. Alternatively, the lower spacer layer 11 and the upper spacer layer 13, both of which are AlGaAsP layers, are formed to have a composition ratio of P in the group V element being 2.5%, so as to cancel out the crystal strain. For the active layer 12 including five quantum well layers, the total compressive strain in that active layer 12 is 36% nm (5×0.9%×8 nm=36% nm). To cancel out crystal strain in each laminate body 10, the lower spacer layer 11 and the upper spacer layer 13 having a total thickness of 80 nm are formed to have a tensile strain of 0.45% in total. Alternatively, the lower spacer layer 11 and the upper spacer layer 13, both of which are AlGaAsP layers, are formed to have a composition ratio of P in the group V element being 13%, so as to cancel out the crystal strain.

The first embodiment as described above adopts the multi-junction structure and enables a reduction in the accumulation of crystal strain. Thus, the first embodiment achieves higher output power.

The total amount of crystal strain of the lower spacer layer 11 and the upper spacer layer 13 included in the resonator region 103 is preferably in a range of −1.1 εactive to −0.9εactive where εactive is the total amount of crystal strain of the active layer 12 included in the resonator region 103.

In addition, when the crystal strain is to be compensated by the barrier layer, the quantum well layer including the compressive strain, and the barrier layer including the tensile strain is repeatedly stacked while being in direct contact with each other, so that the growth window becomes narrow. However, a part of the crystal strain may be compensated not only by the lower spacer layer 11 and the upper spacer layer 13 but also by the barrier layer within a range in which the influence on the growth window is small. In this case, the amount of the tensile strain compensated by the lower spacer layer 11 and the upper spacer layer 13 may be reduced. The total amount of a crystal strain opposite to another crystal strain of the quantum well layer of the active layer 12 included in the resonator region 103 is preferably in a range from −1.1 εactive to −0.9 εactive where εactive is the total amount of said another crystal strain of the quantum well layer of the active layer included in the resonator region 103.

In the present embodiment, the active layers 12 are arranged at a pitch of λ/2, and multiple portions acting as λ/2 resonators are provided. This enables a reduction in temperature variations between the active layers 12. For example, such a configuration allows substantially the same degree of heat dissipation between the uppermost active layer 12 and the lowermost active layer 12 irrespective of the presence of a heatsink below the lower electrode 106. The decrease in heat dissipation may cause a decrease in gain due to carrier leakage, deterioration in characteristics and properties during continuous driving, and the like, and the temperature variation may cause variations in property contribution between the active layers 12. the present embodiment enables a reduction in those issues. This configuration (i.e., the active layers 12 are arranged at a pitch of λ/2 to provide multiple portions acting as λ/2 resonators) exhibits more successful heat dissipation properties than a configuration in which the active layers 12 are arranged at a pitch of A to provide multiple portions acting as 2 resonators. This advantageous effect is marked particularly when the surface-emitting laser devices are arranged in a high-density array.

The present embodiment with the active layer 12 arranged at a pitch of λ/2 enables a reduction in the lateral carrier diffusion in each of the active layers 12, irrespective of the distance from the current confinement layer 108 (i.e., the present embodiment can reduce the lateral carrier diffusion even in the active layer 12 furthest from the current confinement layer 108) and thus allows a high gain in each active layer 12.

In the present embodiment, the resonator region 103 includes multiple (i.e., three) portions, each acting as a λ/2 resonator. Further, the uppermost layer of the lower DBR 102 is the high refractive index layers 102a of n-Al_{0.1}Ga_{0.9}As, and the lowermost layer of the upper DBR 104 is the high refractive index layers 104a of p-Al_{0.1}Ga_{0.9}As. In this configuration, the resonator region 103 is composed of material that forms a low refractive index layer as a whole. However, since the material of the active layer 12 is determined by the wavelength of light to be output, the refractive index is adjusted by the materials of the lower spacer layer 11 and the upper spacer layer 13.

The lower spacer layer 11 and the upper spacer layer 13, which are, for example, AlGaAs layers, have lower refractive indexes with an increasing composition ratio of Al in the group III element. However, with an increasing composition ratio of Al in the group III element, a non-radiative recombination center more likely forms, which is caused by a small amount of oxygen in the AlGaAs layer. This might cause lower properties and reliability. By contrast, the lower spacer layer 11 and the upper spacer layer 13, which are, for example, AlGaAsP layers, have lower refractive indexes with an increasing composition ratio of P in the group V element. This indicates that the refractive indexes of the lower spacer layer 11 and the upper spacer layer 13 can be sufficiently low without increasing the composition ratio of Al in the group III element. For example, with an Al composition ratio of 65%, the P composition ratio of 7.5% allows the low refractive index of the lower spacer layer 11 and the upper spacer layer 13, which is sufficient to achieve the intended performance. For another example, with an Al composition ratio of 60%, the P composition ratio of 13% allows the low refractive index of the lower spacer layer 11 and the upper spacer layer 13, which is sufficient to achieve the intended performance. The Al composition ratio in the group III elements constituting the lower spacer layer 11 and the upper spacer layer 13 is preferably 65% or less from the viewpoint of reducing the formation of the non-radiative recombination center.

Further, the lower spacer layer 11 and the upper spacer layer 13, which are, for example, AlGaAsP layers, facilitate a reduction in the lateral carrier diffusion more than the lower spacer layer 11 and the upper spacer layer 13 being AlGaAs layers. The lower spacer layer 11 and the upper spacer layer 13 may be AlGaInAsP layers.

In the present embodiment, all of the spacer layers (the lower spacer layers 11 and the upper spacer layers 13) included in the resonator region 103 are strain relaxation layers including strain opposite to another strain in the active layer 12. In some examples, at least part of the spacer layer may be a strain relaxation layer. For example, in each pair of the lower spacer layer 11 and the upper spacer layer 13, one of the lower spacer layer 11 and the upper spacer layer 13 includes a crystal strain opposite to another crystal strain in the active layer, and the other one includes no crystal strain. Alternatively, one spacer layer includes a portion of a crystal strain opposite to another crystal strain in the active layer and another portion of no crystal strain. Further, in some examples, only part of the multiple laminate bodies 10 has a strain relaxation layer. In some other examples, only the lowermost lower spacer layer 11 and the uppermost upper spacer layer 13 in the resonator region 103 have crystal strain. However, the configuration in which at least part of the spacer layers included in each laminate body 10 has a strain relaxation layer reduces accumulated strain more significantly and allows more laminate bodies stacked in the resonator region 103. In other words, such a configuration is more advantageous.

### Method for Manufacturing Surface-Emitting Laser Device

A method for manufacturing the surface-emitting laser device 100 according to the first embodiment will be described. The method for the surface-emitting laser device 100 involves metal-organic chemical vapor deposition (MOCVD) or molecular beam epitaxy (MBE) for growing epitaxial films to form a semiconductor layer. More specifically, the lower DBR 102, the resonator region 103, the upper DBR 104, and the contact layer 105 are formed in that order by crystal growth on the substrate 101. A p-AlAs layer serving as the current confinement layer 108 is formed at the boundary between the resonator region 103 and the upper DBR 104.

Then, the semiconductor layer is removed by etching until the side surface of the p-AlAs layer is exposed so that a mesa 109 is formed. The etching for forming the mesa 109 may be dry etching. The mesa 109 when viewed from the top surface may have any shape such as an ellipse, a square, or a rectangle in addition to a circle.

After the formation of the mesa 109, a heat treatment is performed in water vapor to first oxidize an exposed side surface of the p-AlAs layer, which is to serve as the current confinement layer 108, and form an insulator such as AlxOy. Thus, a selectively-oxidized region 108a is formed. Forming such a selectively-oxidized region 108a in the p-AlAs layer creates the current confinement region 108b at a non-oxidized central portion of the p-AlAs layer, which allows the path of the drive current to be limited to the current confinement region 108b at the central portion. Such a structure may be referred to as a current confinement structure.

Then, a protective layer 151 made of a dielectric such as SiN is formed on the entire surface including the side surface and the upper surface of the mesa 109. Further, during the formation of the mesa 109, a region obtained by etching the semiconductor layer is filled with polyimide to be planarized, thus forming a resin layer 152. Thereafter, the protective layer 151 and the resin layer 152 on the contact layer 105 are removed to form the upper electrode 107 serving as the p-side individual electrode around the region on the contact layer 105 from which laser light is emitted. A lower electrode 106 serving as an n-side common electrode is formed on the back surface of the substrate 101.

In the present embodiment, the protective layer 151 covering the side surface of the semiconductor layer and the bottom surface of the surrounding area of the mesa 109, which are exposed by forming the mesa 109, enhances the reliability of the surface-emitting laser device 100. This configuration exhibits such advantage particularly for a semiconductor layer containing Al that is susceptible to corrosion.

In some embodiments, the lowermost high refractive index layers 104a of p-Al_{0.1}Ga_{0.9}As included in the upper DBR 104 and the uppermost upper spacer layer 13 included in the resonator region 103 are in direct contact with each other, and the current confinement layer 108 is above the lowermost high refractive index layers 104a of p-Al_{0.1}Ga_{0.9}As. In this configuration, the surface-emitting laser device 100 is configured to include the node of the normalized longitudinal mode is located at the boundary between the high refractive index layers 104a of p-Al_{0.1}Ga_{0.9}As and the upper spacer layer 13 by adjusting the optical thickness of the uppermost upper spacer layer 13 included in the resonator region 103. In this case, the current confinement layer 108 as a whole is included in the upper DBR 104, and the resonator region 103 does not include the current confinement layer 108.

### Second Embodiment

The second embodiment will be described. A surface-emitting laser device according to the second embodiment has a tunnel-junction VCSEL device structure of 940 nm similarly in the first embodiment, but the material of the tunnel junction layer 20 is different from that of the first embodiment. In the first embodiment, the p-type layer 21 is p⁺⁺-GaAs layer in the first embodiment, and the n-type layer 22 is n⁺⁺-GaAs layer. By contrast, in the second embodiment, the p-type layer 21 is p⁺⁺-GaInAs layer, and the n-type layer 22 is n⁺⁺-GaInAs layer. The p-type layer 21 composed of the p⁺⁺-GaInAs layer and the n-type layer 22 composed of the n⁺⁺-GaInAs layer in the second embodiment cause a reduction in band gap energy more than the first embodiment. This allows a reduction in the electrical resistance of the tunnel barrier for the same doping concentration, and thus facilitates the flow of tunnel currents. From another point of view, when the same tunnel current is fixed, the doping concentration can be further reduced. Since the optical absorption loss is reduced by reducing the doping concentration, the laser output power is enhanced.

Notably, the compressive strain might be accumulated in the tunnel junction layer 20 composed of the GaInAs layer as described above for the active layer 12 of the first embodiment. As described above for the first embodiment, the total compressive strain in the active layer 12 including three quantum well layers is 21.6% nm, and the total compressive strain in the active layer 12 including one quantum well layer is 7.2% nm. Further, the total compressive strain in the active layer 12 including five quantum well layers is 36% nm.

In the second embodiment, the compressive strain of the tunnel junction layer 20 including the GaInAs layer is also taken into consideration. The tunnel junction layer 20 includes two GaInAs layers for a p-type layer 21 and an n-type layer 22, respectively. Since the maximum In composition is the same as that of the active layer, the maximum value of the amount of strain in one layer of the quantum well layer is 0.9%. If the In composition is higher than that maximum In composition, the light emission in the quantum well layer is absorbed by the tunnel junction layer 20. For this reason, the maximum In composition is set the same as that of the active layer. each of the p-type layer 21 and the n-type layer 22 has a thickness of 10 nm to 20 nm. With a thickness of each of the p-type layer 21 and the n-type layer 22 being 10 nm or greater, the intended function of the tunnel junction is achieved. With a thickness of either one of the p-type layer 21 and the n-type layer 22 exceeding 20 nm, light absorption may occur. In view of such circumstances, the total compressive strain of, for example, two tunnel junction layers 20 (i.e., two pairs of p-type layers 21 and n-type layers 22) is 72% nm at the maximum (2 pairs×0.9%×40 nm=72% nm).

When the amount of strain of the quantum well layer and the amount of strain of the tunnel junction layer are added together, the total maximum amount is 108% nm. The spacer layers having a thickness of 80 nm in total and a tensile strain of 1.35% can cancel out the crystal strain.

### Third Embodiment

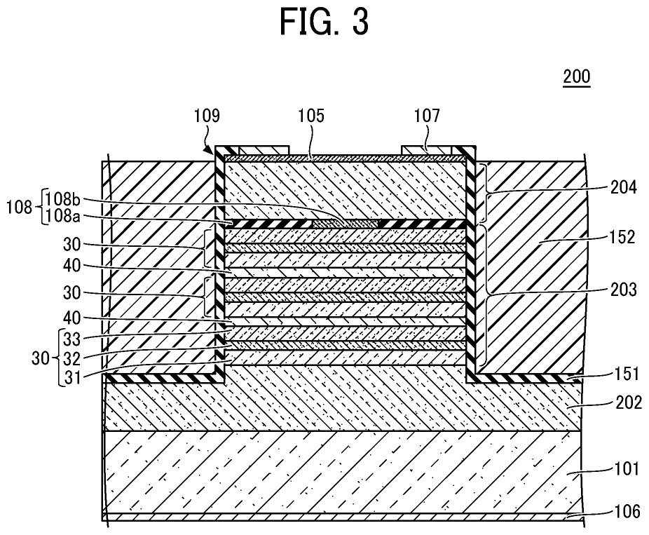

The third embodiment will be described. The third embodiment is different from the first embodiment in material system and oscillation wavelength λ. FIG. 3 is a cross-sectional view of a surface-emitting laser device according to a third embodiment of the present disclosure.

The surface-emitting laser device 200 according to the third embodiment is a surface-emitting laser device whose oscillation wavelength 2 is 680 nm. The surface-emitting laser device 200 includes a substrate 101, a lower DBR 202 (the first reflector), a resonator region 203, an upper DBR 204 (the second reflector), a contact layer 105, a lower electrode 106, and an upper electrode 107. The lower DBR 202 overlies the substrate 101, and the resonator region 203 overlies the lower DBR 202. The upper DBR 204 overlies the resonator region 203, and the contact layer 105 overlies the upper DBR 204. The lower DBR 202, the resonator region 203, the upper DBR 204, and the contact layer 105 are formed by laminating semiconducting layers on the upper surface (a first surface) of the substrate 101. The surface-emitting laser device 200 emits a laser beam upward from the resonator region 203. The surface-emitting laser device 200 is a top-emitting VCSEL device.

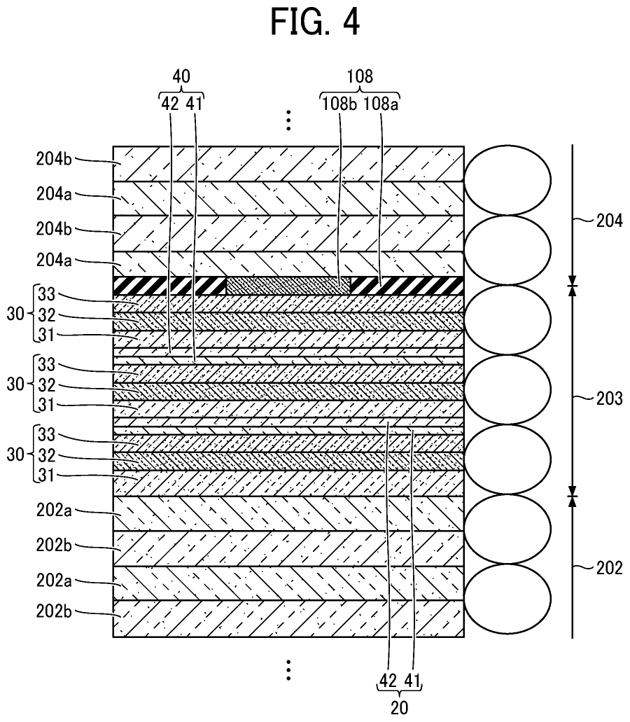

The substrate 101 is composed of an n-GaAs substrate which is a semiconductor substrate. The lower DBR 202 is formed by alternately stacking 45 pairs of high refractive index layers 202a of n-Al_{0.5}Ga_{0.5}As and low refractive index layers 202b of n-Al_{0.9}Ga_{0.1}As, each layer having an optical thickness of λ/4 (see FIG. 4). In other words, the lower DBR 202 includes 45 high refractive index layers 202a of n-Al_{0.5}Ga_{0.5}As and 45 low refractive index layers 202b of n-Al_{0.9}Ga_{0.1}As.

The resonator region 203 includes three laminate bodies 30 stacked on each other. The resonator region 203 further includes a tunnel junction layer 40 between the laminate bodies 30 adjacent to each other in the thickness direction of the surface-emitting laser device 100. Each laminate body 30 includes a lower spacer layer 31, an active layer 32, and an upper spacer layer 33. In each laminate body 30, the active layer 32 overlies the lower spacer layer 31, and the upper spacer layer 33 overlies the active layer 32. The tunnel junction layer 40 includes a p-type layer 41 and an n-type layer 42 (see FIG. 4). The n-type layer 42 overlies the p-type layer 41.

The lower spacer layer 31 and the upper spacer layer 33 are, for example, (Al_{0.7}Ga_{0.3})_{0.52}In_{0.48}P layers. The active layer 32 has a quantum well structure in which GaInP quantum well layers and (Al_{0.5}Ga_{0.5})_{0.51}In_{0.49}P barrier layers are alternately stacked. For example, the GaInP quantum well layer has a thickness of 8 nm. For example, three GaInP quantum well layers are included in one active layer 32. The lattice constant of the active layer 32 having such a composition is greater than the lattice constant of GaAs constituting the substrate 101. The lattice constant of (Al_{0.7}Ga_{0.3})_{0.52}In_{0.48}P constituting the lower spacer layer 31 and the upper spacer layer 33 are smaller than the lattice constant of GaAs. The total thickness of the lower spacer layer 31 and the upper spacer layer 33, which may vary with the position of the laminate body 30, are approximately 60 nm. In the present embodiment, the GaInP quantum well layer contains crystal strain of 0.5% with respect to the GaAs substrate in a compressive direction.

The p-type layer 41 is a p⁺⁺-(Al_{0.2}Ga_{0.8})_{0.51}In_{0.49}P layer having a p-type impurity concentration of 10¹⁹ cm⁻³ or more, and the n-type layer 42 is an n⁺⁺-(Al_{0.2}Ga_{0.8})_{0.51}In_{0.49}P layer having an n-type impurity concentration of 10¹⁹ cm⁻³ or more. The p-type layer 41 and the n-type layer 42 are stacked on each other to form a tunnel junction. Electrons in the conduction band of the n-type layer 42 move toward the valence band of the p-type layer 41, so that a tunnel current flows between the bands. The tunnel junction layer 40 converts the polarity of the charge carrying the current from n-type to p-type.

The upper DBR 204 is formed by alternately stacking 32 pairs of high refractive index layers 204a of p-Al_{0.5}Ga_{0.5}As and low refractive index layers 204b of p-Al_{0.9}Ga_{0.1}As, each layer having an optical thickness of λ/4 (see FIG. 4). In other words, the upper DBR 204 includes 32 high refractive index layers 204a of p-Al_{0.5}Ga_{0.5}As and 32 low refractive index layers 204b of p-Al_{0.9}Ga_{0.1}As.

The surface-emitting laser device 200 includes a current confinement layer 108 between the uppermost laminate body 30 among the three laminate bodies 30 and the lowermost high refractive index layer 204a of p-Al_{0.5}Ga_{0.5}As among 32 high refractive index layers 204a of p-Al_{0.5}Ga_{0.5}As. The current confinement layer 108 includes a selectively-oxidized region 108a and a current confinement region 108b. A lower portion of the current confinement layer 108 is included in the resonator region 203, and an upper portion of the current confinement layer 108 is included in the upper DBR 204.

The contact layer 105 is formed of p-GaAs. A mesa 209 is formed in part of the contact layer 105, the upper DBR 204, the resonator region 203, and the lower DBR 202. The surface-emitting laser device 200 includes a protective layer 151 that covers the side surface of the mesa 209 and the upper surface of the lower DBR 202. Further, a resin layer 152 is formed by embedding a resin material such as polyimide in a region created by removing the semiconductor layer to form the mesa 109.

The resonator region 203 is described below in more detail. FIG. 4 is a cross-sectional view of a part of the surface-emitting laser device 200 according to the third embodiment. The waveform illustrated on the right side of the cross-sectional structure in FIG. 4 schematically indicates the waveform of the normalized longitudinal mode.

In the surface-emitting laser device 200, the optical thickness of each of the laminate bodies 30 is λ/2 or less, and an antinode of the normalized longitudinal mode is located at each of the active layers 32.

The lowermost laminate body 30 among the laminate bodies 30 and the p-type layer 41 immediately above the lowermost laminate body 30 have an optical thickness λ/2 in total. A node of the normalized longitudinal mode is located at the boundary between the lowermost laminate body 30 and the lower DBR 202, and another node is located at the boundary between the p-type layer 41 and the n-type layer 42 included in the tunnel junction layer 40 immediately above the lowermost laminate body 30. This indicates that the lowermost laminate body 30 and the p-type layer 41 immediately above the lowermost laminate body 30 serve as one λ/2 resonator.

The central laminate body 30 among the laminate bodies 30, the n-type layer 42 immediately below the central laminate body 30, and the p-type layer 41 immediately above the central laminate body 30 have an optical thickness λ/2 in total. A node of the normalized longitudinal mode is located at the boundary between the p-type layer 41 and the n-type layer 42 included in the tunnel junction layer 40 immediately below the central laminate body 30, and another node is located at the boundary between the p-type layer 41 and the n-type layer 42 included in the tunnel junction layer 40 immediately above the central laminate body 30. This indicates that the central laminate body 30, the n-type layer 42 immediately below the central laminate body 30, and the p-type layer 41 immediately above the central laminate body 30 serve as one λ/2 resonator.

The uppermost laminate body 30 among the laminate bodies 30, the n-type layer 42 immediately below the uppermost laminate body 30, and a portion of the current confinement layer 108 immediately above the uppermost laminate body 30 have an optical thickness λ/2 in total. A node of the normalized longitudinal mode is located at the boundary between the p-type layer 41 and the n-type layer 42 included in the tunnel junction layer 40 immediately below the uppermost laminate body 30, and another node is located at the portion of the current confinement layer 108 immediately above the uppermost laminate body 30. This indicates that the uppermost laminate body 30, the n-type layer 42 immediately below the uppermost laminate body 30, and the portion of the current confinement layer 108 immediately above the uppermost laminate body 30 serve as one λ/2 resonator.

The optical thickness of the resonator region 203 is 3λ/2.

In the present embodiment as described above, the lattice constant of the active layer 32 is greater than the lattice constant of GaAs constituting the substrate 101, and the lattice constants of the lower spacer layer 31 and the upper spacer layer 33 are smaller than the lattice constant of GaAs. In this configuration, the active layer 32 contains a compressive strain, and the lower spacer layer 31 and the upper spacer layer 33 contain a tensile strain. In other words, the lower spacer layer 31 and the upper spacer layer 33 contain crystal strain in a direction opposite to the direction of the crystal strain of the active layer 32 in the in-plane direction. In each laminate body 30, the crystal strain of the active layer 32 and the crystal strain of the lower spacer layer 31 and the upper spacer layer 33 are canceled out.

In the present embodiment, the GaInP quantum well layer included in the active layer 32 has a crystal strain of 0.5% in the compressive direction and a thickness of 8 nm. For the active layer 32 including three GaInP quantum well layers stacked on each other, the total compressive strain in the active layer 32 is 12% nm (3×0.5%×8 nm=12% nm). The lower spacer layer 31 and the upper spacer layer 33 having a total tensile strain of 12% nm in one laminate body 30 cancel out the crystal strain in the laminate body 30. To cancel out crystal strain in each laminate body 30, the lower spacer layer 31 and the upper spacer layer 33 having a total thickness of 60 nm are formed to have a tensile strain of 0.2% in total. Alternatively, the lower spacer layer 31 and the upper spacer layer 33, both of which are AlGaInP layers, are formed to have a composition ratio of In in the group III element being 48%, so as to cancel out the crystal strain. Since the lattice constant of the (Al_{0.5}Ga_{0.5})_{0.51}In_{0.49}P barrier layer is substantially equal to the lattice constant of the GaAs substrate, the crystal strain is not considered.

The third embodiment as described above adopts the multi-junction structure and enables a reduction in the accumulation of crystal strain. Thus, the third embodiment achieves higher output power.

The surface-emitting laser device 200 according to the third embodiment can be manufactured by the same method as that of the surface-emitting laser device 100 according to the first embodiment.

In the third embodiment, the active layer 32 may contain tensile strain by adjusting the In composition ratio in the group III element of the active layer 32. In addition, the lower spacer layer 31 and the upper spacer layer 33 may contain compressive strain by adjusting the In composition ratio in the group III element in the lower spacer layer 31 and the upper spacer layer 33. The lower spacer layer 31 and the upper spacer layer 33 may be GaInP layers.

In the present disclosure, the total amount of the compressive strain (the first crystal strain) in one active layer is not particularly limited and is, for example, 36% nm or less.

The number of laminate bodies included in the resonator region is not limited to three, and may be one, two, or four or more. When the number of laminate bodies is n (n is a natural number), the total optical thickness of the resonator region is n/2.

The wavelength of light emitted from the surface-emitting laser device is not particularly limited. For example, the surface-emitting laser device may emit light having wavelengths of 780 nm, 808 nm, 980 nm, 1060 nm, 1200 nm, 1300 nm, or 1500 nm.

### Fourth Embodiment

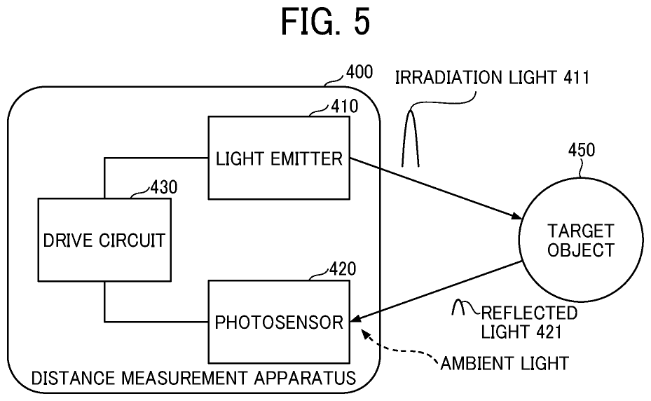

The fourth embodiment is described below. The fourth embodiment relates to a distance measurement apparatus. FIG. 5 is a diagram of a distance measurement apparatus according to the fourth embodiment. The distance measurement apparatus 400 is an example of a detection apparatus.

The distance measurement apparatus 400 according to the fourth embodiment is a distance measurement apparatus using a time of flight (TOF). The distance measurement apparatus 400 includes a light emitter 410, a photosensor 420 (a detector), and a drive circuit 430. The light emitter 410 emits a light beam (irradiation light 411) to a target object 450 to which a distance is to be detected. The photosensor 420 receives reflected light 421 (i.e., light reflected from the target object 450. The drive circuit 430 drives the light emitter 410 and detects the difference between the time at which the light emitter 410 emits a light beam and the time at which the photosensor 420 receives the reflected light 421 to calculate (obtain) a round-trip distance between the distance measurement apparatus 400 and the target object 450 based on the detected time difference. The drive circuit 430 is an example of a calculation unit.

In at least one embodiment, the light emitter 410 includes multiple surface-emitting laser devices 100 of the first embodiment, multiple surface-emitting laser devices 200, multiple surface-emitting laser devices 200 of the third embodiment, or any combinations of the first embodiment, the second embodiment, and the third embodiment.

The repetition frequency of pulses is, for example, in a range from several kilohertz to several tens of megahertz.

The photosensor 420 is, for example, a photodiode (PD), an avalanche photodiode (APD), or a single photon avalanche diode (SPAD). The photosensor 420 may include multiple photosensors arranged in array. The photosensor 420 is an example of a detector.

In the distance measurement using the TOF, it is desirable to separate a signal from a target object to be detected and noise from each other.

With an increasing distance to the target object to be detected, or with a decreasing reflectance of the target object, it is desirable to obtain a signal from the target object using a high-sensitivity photosensor. However, such a high-sensitivity photosensor adversely increases the possibility of an erroneous detection of background light noise or shot noise. To separate the signal and the noise from each other, the threshold value of the light-receiving signal may be increased; however, it may be difficult to receive the signal light from the target object unless the peak output of the emission beam is increased by the amount by which the threshold value of the light receiving signal is increased.

Any one of the surface-emitting laser device 100 according to the first embodiment and the surface-emitting laser device 200 according to the second embodiment or the third embodiment achieves a high-power pulse output. The distance measurement apparatus according to the fourth embodiment achieves both higher accurate detection and longer detectable distance using optical pulse with a high peak output.

### Fifth Embodiment

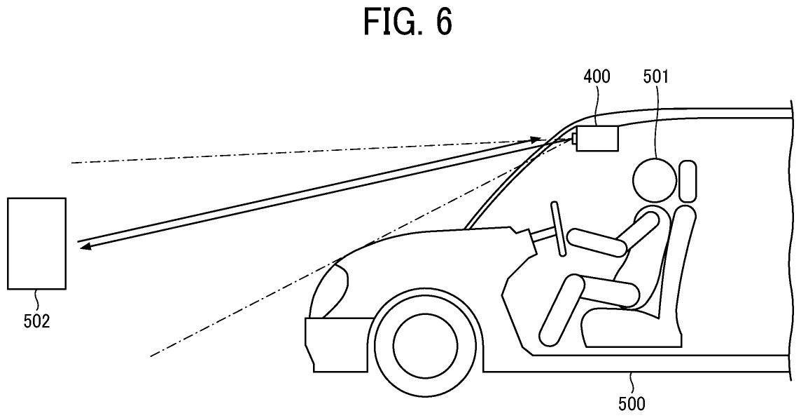

Next, a fifth embodiment will be described. The fifth embodiment relates to a mobile object. FIG. 6 illustrates an automobile 1100 as an example of a mobile object according to the fifth embodiment. The distance measurement apparatus 400 described in the fourth embodiment is provided at an upper portion of a front surface of the automobile 500 (for example, an upper portion of a windshield) as an example of a mobile object according to the fifth embodiment. The distance measurement apparatus 400 measures a distance to an object 502 around the automobile 500. The measurement result of the distance measurement apparatus 400 is input to a controller included in the automobile 500, and the control unit controls the operation of the mobile object based on the measurement result. Alternatively, the controller may provide warning indication on a display provided in the automobile 500 to a driver 501 of the automobile 500 based on the measurement result of the distance measurement apparatus 400.

As described above, in the fifth embodiment, since the distance measurement apparatus 400 is provided in the automobile 500, the position of the object 502 in the periphery of the automobile 500 can be recognized with high precision. The installation position of the distance measurement apparatus 400 is not limited to the upper and front portion of the automobile 500, and may be installed at a side surface or a rear portion of the automobile 500. In this embodiment, the distance measurement apparatus 400 is provided in the automobile 500; however, the distance measurement apparatus 400 may be provided in an aircraft or a ship. Still alternatively, the distance measurement apparatus 400 may be provided in mobile objects such as drones and robots that autonomously move without a driver.

### Sixth Embodiment

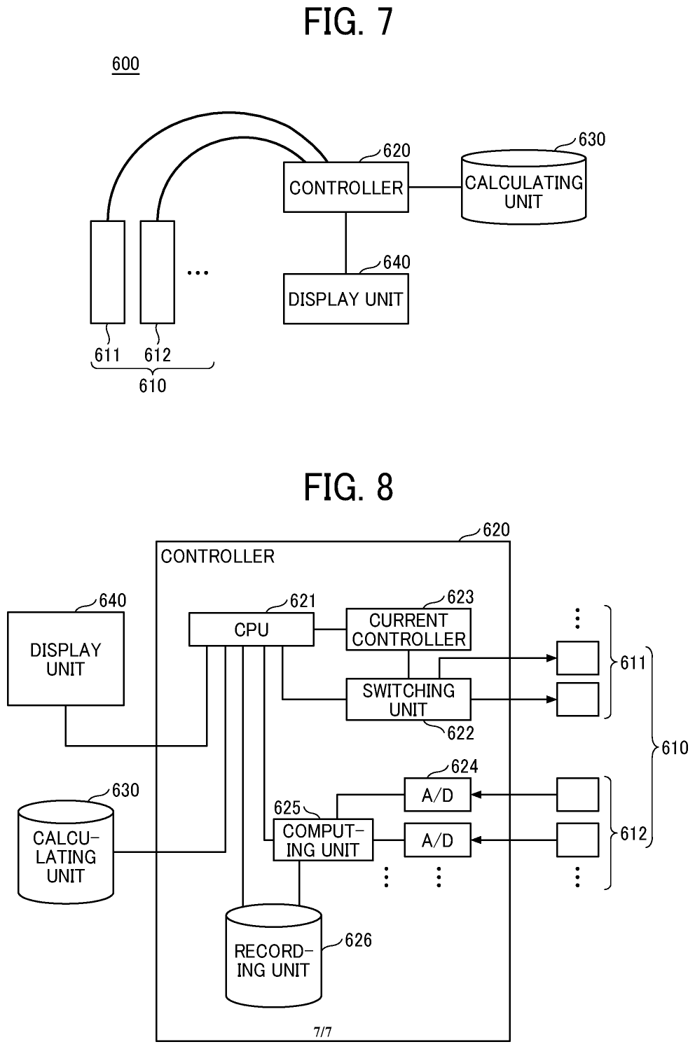

The sixth embodiment will be described. The sixth embodiment relates to an optical examination apparatus. FIG. 7 is a diagram of the configuration of an optical examination apparatus according to a sixth embodiment of the present disclosure. FIG. 8 is a block diagram of the configuration of an optical examination apparatus in FIG. 7.

For example, the optical examination apparatus 600 of the sixth embodiment is used for the diffuse optical tomography (DOT). The DOT is a technique for estimating optical characteristics inside an object by irradiating the object (scattering body) such as a living body with light and detecting the light propagated inside the object. In particular, the application of aids for differential diagnosis of depression, and the application of ancillary equipment of rehabilitation, by detecting the bloodstream inside a brain, are expected.

The optical examination apparatus 600 includes an optical sensor 610, a controller 620, a calculation unit 630, and a display unit 640. The optical sensor 610 includes an irradiation system including multiple light source modules 611 and a detection system including multiple detection modules 612. The irradiation system serves to emit light to an object, and the detection system serves to detect light that has been emitted from the irradiation system to the object and propagated through the object. Each of the light source modules 611 and the detection modules 612 is connected to the controller 620 through the electrical wiring.

As illustrated in FIG. 8, the controller 620 includes, for example, a central processing unit (CPU) 621, a switching unit 622, a current controller 623, an analog-to-digital (A/D) converter 624 (in FIG. 8, the A/D converter 624 is indicated as “A/D”), a computing unit 625, and a recording unit 626. The controller 620 controls the switching unit 622 in accordance with information from the CPU 621, to select a light source module 611 from the multiple light source modules 611. In so doing, the current that is supplied to the light source module 611 through the switching unit 622 is controlled by the current controller 623 to have a desired value. The detection result (data) of the detection module 612 is A/D converted by the A/D converter 624, and operation such as averaging is performed at the computing unit 625. The results of the operation performed at the computing unit 625 are sequentially stored in the recording unit 626.

In at least one embodiment, the light source modules 611 are multiple surface-emitting laser devices 100 of the first embodiment, multiple surface-emitting laser devices 200 of the second embodiment, or multiple surface-emitting laser devices 200 of the third embodiment, or any combinations of those of the first embodiment, the second embodiment, and the third embodiment. In the present embodiment, it is preferable that the wavelengths of the light beams emitted from the surface-emitting lasers are either in the 780 nm band or the 900 nm band, or are selectable from two types of surface-emitting lasers in the 780 nm band and the 900 nm band. As described above, the surface-emitting laser device 100 of the first embodiment, the surface-emitting laser device 200 of the second embodiment, or the surface-emitting laser device 200 of the third embodiment has a higher output power than conventional surface-emitting laser devices. In at least one embodiment, the optical examination apparatus 600 incorporates the surface-emitting laser including multiple surface-emitting laser devices 100 of the first embodiment, multiple surface-emitting laser devices 200 of the second embodiment, or multiple surface-emitting laser devices 200 of the third embodiment, or any combinations of those of the first embodiment, the second embodiment, and the third embodiment. Such an optical examination apparatus 600 achieves higher accurate measurement.

Although the desirable embodiments and so forth have been described in detail, the present disclosure is not limited to the above-described embodiments and so forth, and various modifications and substitutions can be made without departing from the scope and spirit of the present disclosure as set forth in the claims.

The following describes aspects of the present disclosure.

### Aspect 1

A surface-emitting laser device includes: a first reflector; a second reflector; and a resonator region between the first reflector and the second reflector. The resonator region includes: multiple active layers each having first crystal strain in one of a compression direction and a tension direction; a tunnel junction layer between the multiple active layers; and a strain relaxation layer having second crystal strain in another of the compression direction and the tension direction opposite to the first crystal strain of the multiple active layers.

### Aspect 2

In the surface-emitting laser device according to Aspect 1, the strain relaxation layer is between the first reflector and one of the multiple active layer closest to the first reflector.

### Aspect 3

In the surface-emitting laser device according to Aspect 1, the strain relaxation layer is between the multiple active layers.

### Aspect 4

In the surface-emitting laser device according to Aspect 1, the strain relaxation layer is between the second reflector and one of the multiple active layers closest to the second reflector.

### Aspect 5

The surface-emitting laser device according to Aspect 4, further including a current confinement layer between the strain relaxation layer and the second reflector.

### Aspect 6

In the surface-emitting laser device according to Aspect 1, the multiple active layers each has the first crystal strain in the compression direction; and the strain relaxation layer has the second crystal strain in the tension direction.

### Aspect 7

In the surface-emitting laser device according to Aspect 1, the resonator region further includes multiple spacer layers. At least a part of the multiple spacer layers includes the strain relaxation layer.

### Aspect 8

In the surface-emitting laser device according to Aspect 1, the resonator region further includes multiple laminate bodies. Each of the multiple laminate bodies includes: the first spacer layer; the second spacer layer; and one active layer of the multiple active layers, said one active layer between the first spacer layer and the second spacer layer. At least one of the first spacer layer and the second spacer layer includes the strain relaxation layer.

### Aspect 9

In the surface-emitting laser device according to Aspect 8, the resonator region has an optical thickness of nλ/2 in total where λ is a wavelength of light emitted from the multiple active layers, and n is a number of the multiple laminate bodies and is a natural number of 2 or more.

### Aspect 10

In the surface-emitting laser device according to Aspect 8, each of the multiple laminate bodies has an optical thickness of λ/2 or less.

### Aspect 11

In the surface-emitting laser device according to any one of Aspect 1 to Aspect 10, a total amount of the second crystal strain in the resonator region is in a range from −1.18 to −0.98, where ε is a total amount of the first crystal strain in the resonator region.

### Aspect 12

In the surface-emitting laser device according to any one of Aspect 1 to Aspect 11, the tunnel junction layer has third crystal strain in said one of the compression direction and the tension direction. A total amount of each of the first crystal strain of the multiple active layers and the third crystal strain of the tunnel junction layer is 108% nm or less.

### Aspect 13

In the surface-emitting laser device according to any one of Aspect 1 to Aspect 12, an amount of the first crystal strain of each of the multiple active layers is 36% nm or less.

### Aspect 14

In the surface-emitting laser device according to any one of Aspect 1 to Aspect 13, the strain relaxation layer contains phosphorus (P).

### Aspect 15

In the surface-emitting laser device according to Aspect 14, the strain relaxation layer is an AlGaAsP layer or an AlGaInAsP layer.

### Aspect 16

In the surface-emitting laser device according to Aspect 14, the strain relaxation layer is an AlGaInP layer or a GaInP layer.

### Aspect 17

In the surface-emitting laser device according to any one of Aspect 1 to Aspect 16, an Al composition ratio of a group III element in the strain relaxation layer is 65% or less.

### Aspect 18

A detection apparatus includes: the surface-emitting laser device according to any one of Aspect 1 to Aspect 17 configured to emit light to a target object; and a detector configured to detect the light reflected from the target object.

### Aspect 19

The detection apparatus according to Aspect 18, further includes a calculator configured to calculate a distance between the detector and the target object based on a signal from the detector.

### Aspect 20

A mobile object comprising the detection apparatus according to Aspect 19.

The above-described embodiments are illustrative and do not limit the present invention. Thus, numerous additional modifications and variations are possible in light of the above teachings. For example, elements and/or features of different illustrative embodiments may be combined with each other and/or substituted for each other within the scope of the present invention.

This patent application is based on and claims priority to Japanese Patent Application No. 2022-037461, filed on Mar. 10, 2022 and Japanese Patent Application No. 2022-204673, filed on Dec. 21, 2022, in the Japan Patent Office, the entire disclosure of which is hereby incorporated by reference herein.

### REFERENCE SIGNS LIST

100, 200 surface-emitting laser device
10, 30 laminate body
11, 31 lower spacer layer
12, 32 active layer
13, 33 upper spacer layer
20, 40 tunnel junction layer
21, 41 p-type layer
22, 42 n-type layer
102, 202 lower DBR
103, 203 resonator region
104, 204 upper DBR
400 distance measurement apparatus
430 drive circuit (calculation unit)
500 automobile (mobile object)
600 optical examination apparatus

1. A surface-emitting laser device comprising:
a first reflector;
a second reflector; and
a resonator region between the first reflector and the second reflector, the resonator region including:
multiple active layers each having first crystal strain in one of a compression direction and a tension direction;
a tunnel junction layer between the multiple active layers; and
a strain relaxation layer having second crystal strain in another of the compression direction and the tension direction opposite to the first crystal strain of the multiple active layers.

2. The surface-emitting laser device according to claim 1, wherein:
the strain relaxation layer is between the first reflector and one of the multiple active layer closest to the first reflector.

3. The surface-emitting laser device according to claim 1, wherein:
the strain relaxation layer is between the multiple active layers.

4. The surface-emitting laser device according to claim 1, wherein:
the strain relaxation layer is between the second reflector and one of the multiple active layers closest to the second reflector.

5. The surface-emitting laser device according to claim 4, further including:
a current confinement layer between the strain relaxation layer and the second reflector.

6. The surface-emitting laser device according to claim 1, wherein:
the multiple active layers each has the first crystal strain in the compression direction; and
the strain relaxation layer has the second crystal strain in the tension direction.

7. The surface-emitting laser device according to claim 1, wherein the resonator region further includes:
multiple spacer layers, at least a part of the multiple spacer layers includes the strain relaxation layer.

8. The surface-emitting laser device according to claim 1, wherein:
the resonator region further includes multiple laminate bodies,
each of the multiple laminate bodies including:
a first spacer layer;
a second spacer layer; and
one active layer of the multiple active layers, said one active layer between the first spacer layer and the second spacer layer,
wherein at least one of the first spacer layer and the second spacer layer includes the strain relaxation layer.

9. The surface-emitting laser device according to claim 8, wherein:
the resonator region has an optical thickness of nλ/2 in total:
where λ is a wavelength of light emitted from the multiple active layers, and
n is a number of the multiple laminate bodies and is a natural number of 2 or more.

10. The surface-emitting laser device according to claim 8, wherein;
each of the multiple laminate bodies has an optical thickness of λ/2 or less.

11. The surface-emitting laser device according to claim 1, wherein;
a total amount of the second crystal strain in the resonator region is in a range from −1.1ε to −0.9ε,
where ε is a total amount of the first crystal strain in the resonator region.

12. The surface-emitting laser device according to claim 1, wherein:
the tunnel junction layer has third crystal strain in said one of the compression direction and the tension direction, and
a total amount of each of the first crystal strain of the multiple active layers and the third crystal strain of the tunnel junction layer is 108% nm or less.

13. The surface-emitting laser device according to claim 1, wherein an amount of the first crystal strain of each of the multiple active layers is 36% nm or less.

14. The surface-emitting laser device according to claim 1, wherein:
the strain relaxation layer contains phosphorus (P).

15. The surface-emitting laser device according to claim 14, wherein:
the strain relaxation layer is an AlGaAsP layer or an AlGaInAsP layer.

16. The surface-emitting laser device according to claim 14, wherein;
the strain relaxation layer is an AlGaInP layer or a GaInP layer.

17. The surface-emitting laser device according to claim 1, wherein;
an Al composition ratio of a group III element in the strain relaxation layer is 65% or less.

18. A detection apparatus comprising:
the surface-emitting laser device according to claim 1 to emit light to a target object; and
a detector to detect the light reflected from the target object.

19. The detection apparatus according to claim 18, further comprising:
calculation circuitry configured to calculate a distance between the detector and the target object based on a signal from the detector.

20. A mobile object comprising the detection apparatus according to claim 19.
